(19) United States
(12) Patent Application Publication
(10) Pub. No.: US 2005/0167281 A1
(43) Pub. Date: Aug. 4, 2005

(54) Production method of suspension board with circuit

(76) Inventors: Tetsuya Ohsawa, Osaka (JP); Yasuhito Ohwaki, Osaka (JP)

Correspondence Address: DICKINSON WRIGHT PLLC, 1901 L. STREET NW, SUITE 800, WASHINGTON, DC, 20036, US

(21) Appl. No.: 11/044,077

(22) Filed: Jan. 28, 2005

(30) Foreign Application Priority Data
Jan. 30, 2004 (JP) 2004-023014

(51) Int. Cl. C23C 14/32; H04R 31/00

(52) U.S. Cl. 205/223; 204/192.17; 216/2

(57) ABSTRACT

A production method of a suspension board with circuit that can reduce variations in diameter of the location holes or like holes formed in the suspension board and can produce a trim contour of the suspension board. In the process of forming a seed film 12, zirconium is previously deposited on a surface of the suspension board 2 by sputtering a conductive material forming the seed film 12 using an electrode formed of zirconium. Or, in the process of forming a metal coating 14, palladium is previously deposited on the surface of the suspension board 2 by electroless-plating the thin metal film forming the metal coating 14 using a catalyst including palladium. Thereafter, the suspension board 2 formed of stainless is trimmed by the chemical etching. This can allow an end face 17 of the suspension board 2 to be chemically etched evenly.

### BACKGROUND OF THE INVENTION

1. Field of the Invention

The present invention relates to a production method of a suspension board with circuit and, more particularly, to a production method of a suspension board with circuit for mounting a magnetic head of a hard disc drive thereon.

2. Description of the Prior Art

A suspension board with circuit is used to mount a magnetic head of a hard disc drive thereon and support the magnetic head closely spaced from a magnetic disk, while holding it against an airflow generated when the magnetic head and the magnetic disk run relative to each other.

This suspension board with circuit usually comprises a suspension board of a stainless, an insulating base layer formed on the suspension board, a conductor layer formed in the form of a wiring circuit pattern on the insulating base layer, and an insulating cover layer, formed on the insulating base layer, to cover the conductor layer.

As described by e.g. JP Laid-open (Unexamined) Patent Publication No. Hei 10-265572, this suspension board with circuit is formed for example by the method that after the respective layers, namely, the suspension board, the insulating base layer, the conductor layer, and the insulating cover layer, are sequentially formed, the suspension board is trimmed into a predetermined pattern by a chemical etching using etching solution such as ferric chloride and cupric chloride.

When the suspension board is trimmed, location holes are also formed in the suspension board, in order to locate the magnetic head when mounted on the suspension board or locate a load beam when spot-welded with the suspension board.

For improvement in accuracy of the mounting location of the magnetic head, the processing accuracy of the location holes is required.

In addition, for improvement in suspension function of the suspension board, the trimming accuracy is also essential.

However, etching the suspension board by the chemical etching as mentioned above produces the problem that end faces of the suspension board chemically etched are corroded unevenly or etched irregularly by the etching solution, so that variations in diameter of the location holes may be caused or a trim contour cannot be obtained.

### SUMMARY OF THE INVENTION

It is the object of the invention to provide a production method of a suspension board with circuit that can reduce variations in diameter of the location holes or like holes formed in the suspension board and can produce a trim contour of the suspension board.

The present invention provides a production method of a suspension board with circuit comprising a process of etching a suspension board, wherein the suspension board is etched in the etching process in the state that material harder to be etched than forming material of the suspension board is deposited on a surface of the suspension board.

In the method of the present invention, it is preferable that the forming material of the suspension board is stainless, and the material harder to be etched than the forming material of the suspension board is zirconium or palladium.

It is preferable that the method of the present invention further comprises a sputtering process of forming a thin conductive film on the surface of the suspension board by sputtering, wherein zirconium is deposited on the surface of the suspension board by sputtering the thin conductive film in the sputtering process using an electrode formed of zirconium.

It is also preferable that the method of the present invention further comprises an electroless plating process of forming a thin metal film on the surface of the suspension board by electroless plating, wherein palladium is deposited on the surface of the suspension board by electroless-plating the thin metal film in the electroless plating process using a catalyst including palladium.

According to the production method of the suspension board with circuit of the present invention, a material harder to be etched than a forming material of the suspension board is deposited on a surface of the suspension board in the process of etching the suspension board. This can allow an end face of the suspension board to be etched evenly using an etching solution and smoothed. This can provide the advantage of producing improvement in working accuracy.

As a result, this method can reduce variations in diameter of the location holes or like holes formed in the process of etching the suspension board and also can produce a trim contour of the suspension board.

### BRIEF DESCRIPTION OF THE DRAWINGS

In the drawings:

FIG. 1 is a plane view showing an embodiment of a suspension board with circuit of the present invention.

FIG. 2 is a process drawing showing a production method of the suspension board with circuit shown in FIG. 1:

(a) shows the process of preparing a suspension board;

(b) shows the process of coating a liquid solution of precursor of photosensitive polyimide resin over the entire surface of the suspension board and then heating the coated liquid solution, thereby forming a coating of the polyimide resin on the suspension board;

(c) shows the process of exposing the coating to light through a photo mask, heating it to a predetermined temperature, if necessary, and developing it, thereby forming the coating into a predetermined pattern;

(d) shows the process of heating the coating to form an insulting base layer of polyimide resin with a predetermined pattern on the suspension board; and

(e) shows the process of forming a seed film of a thin conductive film on the entire surface of the suspension board and insulating base layer.

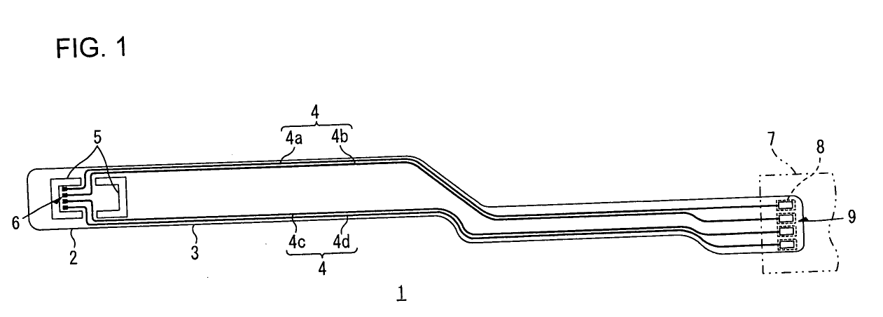

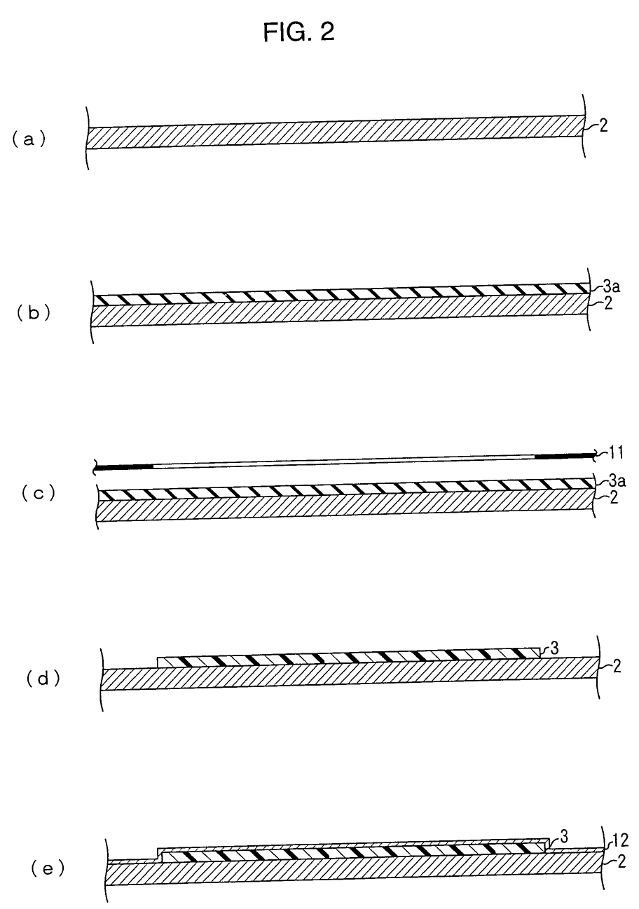

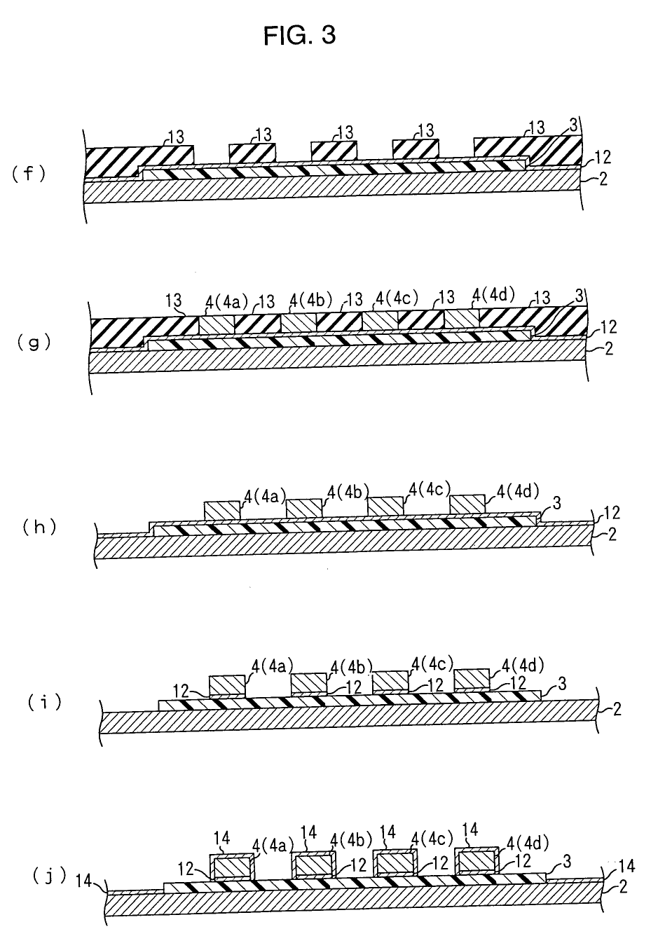

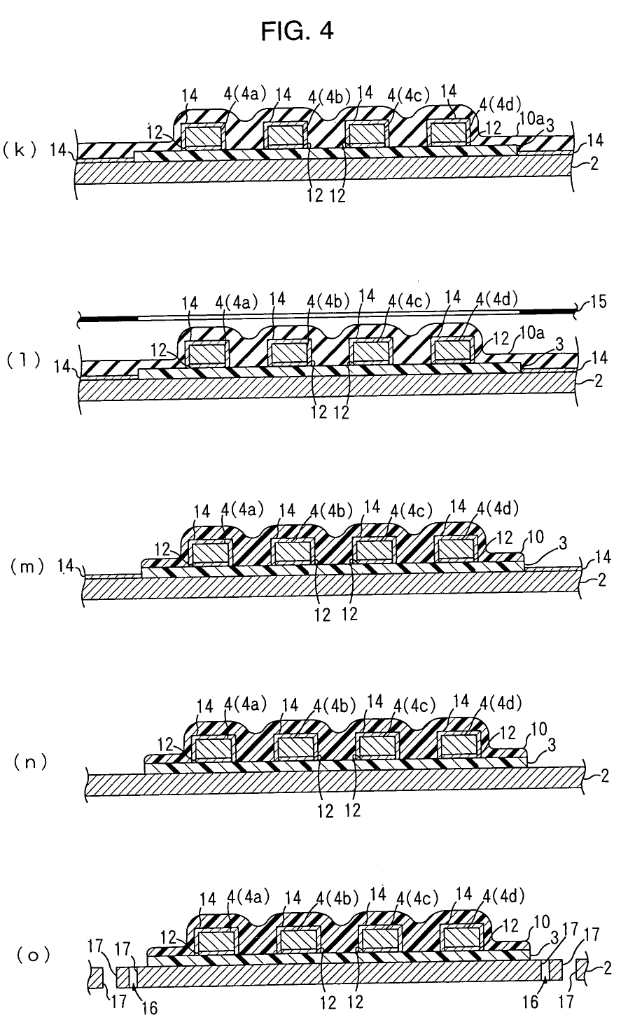

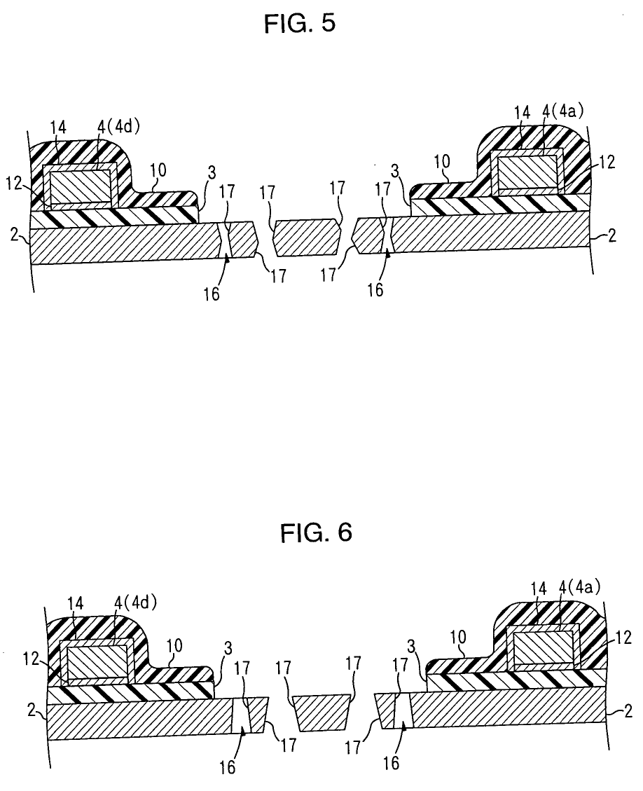

FIG. 3 is a process drawing, which is the sequence of FIG. 2, showing the production method of the suspension board with circuit shown in FIG. 1:

(f) shows the process of forming on the seed film a plating resist having a reverse pattern to a wiring circuit pattern;

(g) shows the process of forming a conductor layer of the wiring circuit pattern by plating on an area of the seed film where the plating resist is not formed;

(h) shows the process of removing the plating resist;

(i) shows the process of removing the part of the seed film where the plating resist was formed; and

(j) shows the process of forming a metal coating of a thin metal film on a surface of the conductor layer and a surface of the suspension board.

FIG. 4 is a process drawing, which is the sequence of FIG. 3, showing the production method of the suspension board with circuit shown in FIG. 1:

(k) shows the process of coating a liquid solution of precursor of photosensitive polyimide resin on the insulating base layer and the metal coating and then heating the coated liquid solution, thereby forming a coating of the polyimide resin on the suspension board;

(l) shows the process of exposing the coating to light through a photo mask, heating it to a predetermined temperature, if necessary, and then developing it, thereby forming the coating into a predetermined pattern;

(m) shows the process of heating the coating to form an insulating cover layer of polyimide resin with a predetermined pattern on the insulating base layer including the conductor layer; and

(n) shows the process of stripping the metal coating; and

(o) shows the process of processing the suspension board into a predetermined pattern by the chemical etching.

FIG. 5 is an enlarged cross sectional view of a principal part of the suspension board trimmed in the process (o) of FIG. 4 (showing the state in which a material harder to be etched than a forming material of the suspension board is not deposited on a surface of the suspension board).

FIG. 6 is an enlarged cross sectional view of a principal part of the suspension board trimmed in the process (o) of FIG. 4 (showing the state in which a material harder to be etched than a forming material of the suspension board is deposited on a surface of the suspension board).

### DETAILED DESCRIPTION OF THE PREFERRED EMBODIMENTS

FIG. 1 is a plane view showing an embodiment of a suspension board with circuit of the present invention. The suspension board with circuit is used to mount thereon a magnetic head of a hard disk drive (not shown) and support the magnetic head closely spaced from a magnetic disk, while holding it against an airflow generated when the magnetic head and the magnetic disk run relative to each other. The suspension board with circuit includes lines of wire, formed integrally in the form of a wiring circuit pattern, for connecting between the magnetic head and a read/write board.

In FIG. 1, the suspension board with circuit 1 comprises a suspension board 2 extending longitudinally, an insulating base layer 3 of insulating material formed on the suspension board 2, and a conductor layer 4 in the form of a wiring circuit pattern formed on the insulating base layer 3. The wiring circuit pattern is in the form of a plurality of lines of wire 4a, 4b, 4c, and 4d spaced apart in parallel with each other with a predetermined interval.

The suspension board 2 is provided, at a front end portion thereof, with gimbals 5 for fitting the magnetic heads therein which are formed by cutting out the suspension board 2. It is also provided, at the front end portion thereof, with a magnetic head connection terminal 6 for connecting between the magnetic head and the lines of wire 4a, 4b, 4c, and 4d.

Also, the suspension board 2 is provided, at a rear end portion thereof, with an external connection terminal portion 9 for connecting between terminals 8 of a read/write board 7 and the lines of wire 4a, 4b, 4c, and 4d.

In practice, an insulating cover layer 10 of insulating material is coated over the conductor layer 4, though not shown in FIG. 1.

Next, a production method of this suspension board with circuit 1 will be described with reference to FIGS. 2-5. It should be noted that in FIGS. 2-5, the suspension board with circuit 1 is shown in section taken along a widthwise direction of the suspension board with circuit 1 (a direction orthogonal to the longitudinal direction of the same).

In this method, the suspension board 2 is prepared, first, as shown in FIG. 2(a).

A metal foil or a thin metal sheet is used as the suspension board 2. For example, stainless steel, 42-alloy, and the like are used for the suspension board 2. Stainless steel is preferably used. Preferably, the suspension board 2 has a thickness of 10-60 μm, or preferably 15-30 μm.

In this method, the suspension board with circuit 1 is produced in the following manner. That is to say, an elongate suspension board 2 is prepared, first. Then, a plurality of patterns are formed by laminating the insulating base layer 3, the conductor layer 4, and the insulating cover layer 10 on the elongate suspension board 2 sequentially. Thereafter, the suspension board 2 is cut out along its contour in the process of chemically etching the suspension board 2 mentioned later.

Then, the insulating base layer 3 is formed with a predetermined pattern on the suspension board 2, as shown in FIG. 2(b) to FIG. 2(d).

The insulating materials that may be used for forming the insulating base layer 3 include, for example, synthetic resins, such as polyimide resin, acrylic resin, polyether nitrile resin, polyether sulfonic resin, polyethylene terephthalate resin, polyethylene naphthalate resin, and polyvinyl chloride resin. Of these synthetic resins, a photosensitive synthetic resin is preferably used for forming the insulating base layer 3 with the predetermined pattern. The photosensitive polyimide resin is further preferably used therefor.

For example when photosensitive polyimide resin is used to form the insulating base layer 3 with the predetermined pattern on the suspension board 2, a liquid solution of precursor of the photosensitive polyimide resin (polyamic acid resin) is coated over the entire surface of the suspension board 2, as shown in FIG. 2(b). Then, the coated polyimide resin is heated at e.g. 60-150° C., or preferably at 80-120° C., to form a coating 3a of the precursor of the photosensitive polyimide resin.

Then, the coating 3a is exposed to light through a photo mask 11, as shown in FIG. 2(c), and, if required, it is heated to a predetermined temperature. Thereafter, the coating 3a is developed to be formed into a predetermined pattern.

Preferably, radiation irradiated through the photo mask 11 has an exposure wavelength of 300-450 nm, or preferably 350-420 nm. Also, an integrated quantity of exposure light is preferably in the range of 100-1,000 mJ/cm², or preferably in the range of 200-700 mJ/cm².

When the exposed-to light portion of the coating 3a irradiated is heated at a temperature of e.g. 130° C. or more to less than 150° C., it is solubilized (positive type) in the next developing process. On the other hand, when heated at a temperature of e.g. 150° C. or more to 180° C. or less, it is insolubilized (negative type) in the next developing process. The development can be performed by any known method, such as a dipping process and a spraying process, using a known developing solution such as alkaline developer. In this method, it is preferable that the pattern is produced with the negative image. Illustrated in FIG. 2 is an embodiment using the process steps for forming the pattern with the negative image.

Then, the coating 3a of the precursor of the photosensitive polyimide resin thus patterned is heated finally to e.g. 250° C. or more to be cured (imidized), whereby the insulating base layer 3 of polyimide resin is formed with the predetermined pattern on the suspension board 2, as shown in FIG. 2(d).

In the case where the photosensitive synthetic resin is not used, for example synthetic resin may be coated over the suspension board 2 with a predetermined pattern or may be adhesively bonded thereto in the form of a dry film having the predetermined pattern.

Preferably, the insulating base layer 3 thus formed has a thickness of e.g. 2-30 μm, or preferably 5-20 μm.

Then, the conductor layer 4 is formed with the wiring circuit pattern on the insulating base layer 3. The conductor layer 4 in the form of the wiring circuit pattern is formed of conductive material. The conductive materials that may be used include, for example, copper, nickel, gold, solder, or alloys thereof Copper is preferably used. The conductor layer 4 in the form of the predetermined wiring circuit pattern can be provided by forming the conductor layer 4 with the predetermined wiring circuit pattern on the insulating base layer 3 by a known patterning process, such as a subtractive process and an additive process.

In the subtractive process, the conductor layer 4 is laminated on the entire surface of the insulating base layer 3 using, if necessary, an adhesive layer, first. Then, an etching resist having the same pattern as the wiring circuit pattern is formed on the conductor layer 4, and the conductor layer 4 is etched using the etching resist as a resist. Thereafter, the etching resist is removed.

In the additive process, a seed film of a thin film of conductive material is formed on the insulating base layer 3, first. Then, after a plating resist having a reverse pattern to the wiring circuit pattern is formed on the seed film, the conductor layer 4 is formed in the form of the wiring circuit pattern by plating on a surface of the seed film on which the plating resist is not formed. Thereafter, the plating resist and the part of the seed film on which the plating resist was laminated are removed.

Of these patterning processes, the additive process is preferably used to form a fine wiring circuit pattern, as shown in FIG. 2(e) to FIG. 3(i).

Specifically, in the additive process, the seed film 12 of a thin film of conductive material is formed on the entire surface of the suspension board 2 and insulating base layer 3, first, as shown in FIG. 2(e).

The seed film 12 is formed using a vacuum vapor deposition process, or preferably using a sputtering process. Chromium and copper are preferably used as the conductive material used for forming the seed film 12. To be more specific, for example a thin chrome film and a thin copper film are preferably formed in sequence on the entire surface of the suspension board 2 and insulating base layer 3 by the sputtering process. Preferably, the thin chrome film has thickness of 100-600 Å and the thin copper film has thickness of 500-2,000 Å.

Sequentially, a plating resist 13 having a reverse pattern to the wiring circuit pattern is formed on the seed film 12, as shown in FIG. 3(f). The plating resist 13 may be formed in the form of the resist pattern mentioned above by a known process using a dry film photoresist, for example.

Then, the conductor layer 4 of the wiring circuit pattern is formed by plating on an area of the seed film 12 where the plating resist 13 is not formed, as shown in FIG. 3(g).

Either of the electrolysis plating and the electroless plating may be used to form the conductor layer 4. Preferably, the electrolysis plating, particularly the electrolytic copper plating, is used therefor. This wiring circuit pattern is, for example, in the form of a pattern shown in FIG. 1 defined by a plurality of lines of wire 4a, 4b, 4c, and 4d spaced apart in parallel with each other with a predetermined interval.

The conductor layer 4 has a thickness of e.g. 2-25 μm or preferably 5-20 μm, and the lines of wire 4a, 4b, 4c, and 4d have each a width of e.g. 10-500 cm or preferably 30-300 μm. The interval between the adjacent lines of wire 4a, 4b, 4c, and 4d is for example in the range of 10-1,000 μm, or preferably 10-500 μm.

Then, the plating resist 13 is removed by a known etching process, such as a chemical etching (wet etching), or by stripping, as shown in FIG. 3(h). Then, the seed film 12 on which the plating resist 13 was formed is removed by a known etching process, such as the chemical etching (wet etching), as shown in FIG. 3(i). After the processes mentioned above, the conductor layer 4 in the form of the wiring circuit pattern is formed on the insulating base layer 3.

Then, a metal coating 14 is formed on a surface of the conductor layer 4, as shown in FIG. 3(j). Preferably, the metal coating 14 is formed by electroless plating in the form of a hard, thin metal film. For example, the metal coating 14 is formed by electroless nickel plating in the form of a hard, thin nickel film. It is enough that the metal coating 14 has a thickness enough to prevent the surface of the conductor layer 4 from being exposed. For example, the thickness of the metal coating 14 is in order of 0.05-0.1 μm. The metal coating 14 is formed on a surface of the suspension board 2 as well by the electroless plating.

Sequentially, an insulating cover layer 10 for covering the conductor layer 4 is formed in a predetermined pattern, as shown in FIG. 4(k) to FIG. 4(m). The same insulating material as that for the insulating base layer 3 is used for forming the insulating cover layer 10. Preferably, photosensitive polyimide resin is used.

When the insulating cover layer 10 is formed using e.g. the photosensitive polyimide resin, a solution of precursor of the photosensitive polyimide resin (polyamic acid resin) is coated over the entire surface of the insulating base layer 3 and metal coating 14, as shown in FIG. 4(k), and then is heated at e.g. 60-150° C., or preferably at 80-120° C., to form a coating 10a of the precursor of the photosensitive polyimide resin. Then, the coating 10a is exposed to light through the photo mask 15, as shown in FIG. 4(l). If required, it is heated to a predetermined temperature. Thereafter, the coating 10a is developed and thereby is patterned so that the conductor layer 4 is covered with the coating 10a.

The coating 10a is exposed to light and developed under the same condition as the condition for exposing and developing the insulating base layer 3. The patterning of the coating 10a is preferably produced with the negative image. Shown in FIG. 4 is an embodied form in which the coating 10a is patterned with the negative image.

Then, the coating 10a of the precursor of the photosensitive polyimide resin thus patterned is heated finally to e.g. 250° C. or more to be cured (imidized), whereby the insulating cover layer 10 of polyimide resin is formed on the insulating base layer 3 including the conductor layer 4, as shown in FIG. 4(m). The insulating cover layer 10 has a thickness of e.g. 1-30 μm, or preferably 2-20 μm.

Then, the metal coating 14 formed on the suspension board 2 is stripped, as shown in FIG. 4(n). Thereafter, the suspension board 2 is processed into a predetermined form by the chemical etching, as shown in FIG. 4(o). The suspension board with circuit 1 is produced by the processes as mentioned above.

In this processing, location holes 16, which are used to locate gimbals 5 and a magnetic head when mounted on the suspension board 2 or locate a load beam when spot-welded with the suspension board 2, are cut out into a predetermined form in the suspension board 2 and also the suspension board 2 is trimmed to define an outer shape of the suspension board 2.

Also, in this processing, the suspension board 2 is chemically etched in the state that a material harder to be chemically etched than a forming material of the suspension board 2 is previously deposited on a surface of the suspension board 2.

No particular limitation is imposed on the material harder to be chemically etched than the forming material of the suspension board 2. For example when the forming material of the suspension board 2 is stainless, zirconium and palladium can be used as the material harder to be etched chemically.

No particular limitation is imposed on the way of allowing the material harder to be etched chemically than the forming material of the suspension board 2 to be previously deposited on the surface of the suspension board 2. For instance, for previously depositing zirconium on the surface of the suspension board 2, for example the conductive material forming the seed film 12 is sputtered by using an electrode formed of zirconium in the process of forming the seed film 12 mentioned above. In this case, zirconium is ejected and dispersed from the electrode by the impact of discharge gas (e.g. argon gas) and the ejected zirconium is deposited on the surface of the suspension board 2.

The zirconium thus deposited on the surface of the suspension board 2 remains on the surface of the suspension board 2 until this process until which a certain amount of zirconium required for chemically etching the suspension board 2 is obtained.

It is preferable that an amount of zirconium deposited on the surface of the suspension board 2 immediately after completion of the sputtering is in the range of e.g. 0.2-15.0 atomic %, and an amount of zirconium deposited thereon immediately before the chemical etching of the suspension board 2 is in the range of e.g. 0.1-10.0 atomic %, or preferably 0.1-5.0 atomic %. When an amount of zirconium deposited on the surface of the suspension board 2 is reduced beyond the above-said range, there is the possibility that the end faces 17 of the suspension board 2 cannot be etched uniformly. On the other hand, when an amount of zirconium deposited on the surface of the suspension board 2 is increased beyond the above-said range, the zirconium serves as a foreign material to cause product deficiency. The amount of zirconium deposited can be determined as an element ratio per unit area by the surface analysis using ESCA.

Also, the amount of zirconium deposited can be adjusted by changing conditions for the sputtering. The sputtering is performed on condition that the electric power is e.g. 0.2 kW or more, or preferably in the range of 1.0-6.5 kW, and the processing time is e.g. 5 seconds or more, or preferably in the range of 10-40 seconds.

For previously depositing palladium on the surface of the suspension board 2, a proper step may be taken without any particular limitation. For example, a hard, thin metal film which forms the metal coating 14 is plated by electroless plating using catalyst including palladium in the process of forming the above-said metal coating 14. In this case, when the suspension board 2 is dipped in electroless plating solution, palladium included as the catalyst in the electroless plating solution is deposited on the surface of the suspension board 2.

The palladium deposited on the surface of the suspension board 2 remains on the surface of the suspension board 2 until this process until which a certain amount of palladium required for chemically etching the suspension board 2 is obtained.

It is preferable that an amount of palladium deposited on the surface of the suspension board 2 immediately after completion of the electroless plating is in the range of e.g. 0.5-15.0 atomic %, and an amount of palladium deposited thereon immediately before the chemical etching of the suspension board 2 is in the range of e.g. 0.1-10.0 atomic %, or preferably 0.1-5.5 atomic %. When an amount of palladium deposited on the surface of the suspension board 2 is reduced beyond the above-said range, there is the possibility that the end faces 17 of the suspension board 2 cannot be etched uniformly. On the other hand, when an amount of palladium deposited on the surface of the suspension board 2 is increased beyond the above-said range, the palladium serves as a foreign material to cause product deficiency. The amount of palladium deposited can be determined as an element ratio per unit area by the surface analysis using ESCA.

Also, the amount of palladium deposited can be adjusted by changing conditions for the electroless plating. For example the electroless plating using palladium hydrochloride solution as the electroless plating solution is performed on condition that the palladium concentration of the palladium hydrochloride solution is in the range of e.g. 35-75 ppm, or preferably 45-60 ppm; the hydrochloric acid concentration is in the range of 90-130 g/L, or preferably 100-120 g/L; the solution temperature is in the range of e.g. 23-27° C.; and the dipping time is e.g. 40 seconds or more, or preferably in the range of 50-80 seconds.

Both zirconium and palladium may be deposited on the surface of the suspension board 2, or either of them may alternatively be deposited thereon.

As obvious from the foregoing, the previous deposition of zirconium or palladium on the surface of the suspension board 2 can eliminate the need of taking an extra step that zirconium or palladium is previously deposited on the surface of the suspension board 2 in the process of producing the suspension board with circuit and can ensure that zirconium or palladium is previously deposited on the surface of the suspension board 2, while providing a reduced number of processes. This can provide simplification of the producing process and improvement of the production efficiency.

For chemically etching the suspension board 2, a proper step can be taken without any particular limitation. For example, all areas of the suspension board 2, except the area of the suspension board 2 to be chemically etched, are covered with a predetermined pattern by using a photoresist or a dry film photoresist. Thereafter, the suspension board 2 is etched using an aqueous solution of e.g. ferric chloride and cupric chloride as the etching solution. Thereafter, it may be washed with water and dried, if required.

In this method, the material harder to be etched than the forming material of the suspension board 2 is previously deposited on the surface of the suspension board 2. This can allow the end faces 17 of the suspension board 2 to be etched evenly by the etching solution and smoothed. This can provide the advantage of producing improvement in working accuracy.

If the material harder to be etched than the forming material of the suspension board 2 is not previously deposited on the surface of the suspension board 2, then the end faces 17 of the suspension board 2 chemically etched may be irregularly etched by the etching solution, as shown in FIG. 5.

On the other hand, if the material harder to be etched than the forming material of the suspension board 2 is previously deposited on the surface of the suspension board 2 in the same manner as in this method, then the end faces 17 of the suspension board 2 chemically etched will be etched evenly by the etching solution and thus can be formed evenly and smoothly, as shown in FIG. 6.

More specifically, in this embodiment, the end faces 17 are formed in a shape extending obliquely from the front side toward the back side regularly in an inward direction with respect to a thickness direction of the suspension board 2 (or a shape increasing in width of an opening regularly from the front side toward the back side).

As a result, this method can reduce variations in diameter of the location holes 16 or like holes formed in the process of etching the suspension board 2 and also can produce a trim contour of the suspension board 2.

In this method, the magnetic head connection terminal portion 6 and the external connection terminal portion 9 may be formed in the following manner, for example. That is to say, openings are previously formed at locations where the magnetic head connection terminal portion 6 and the external connection terminal portion 9 are to be formed in the process of forming the insulating cover layer 10. Then, the metal coating 14 exposed from the openings is removed simultaneously together with the metal coating 14 formed on the suspension board 2. Thereafter, a pad portion comprising a nickel plating layer and a gold plating layer which are formed sequentially by electrolysis nickel plating and electrolysis gold plating is formed on the exposed surface of the conductor layer 4. The nickel plating layer and the gold plating layer have a thickness of e.g. 0.2-5 μm.

In the method mentioned above, the metal coating 14 may be formed before the removal of the seed film 12 as well as after the removal of the seed film 12. To be more specific, for example in the case of the seed film 12 formed by laminating a thin chromium film and a thin copper film sequentially, the metal coating 14 may be formed in such a manner that the thin copper film is removed first, and, then, the metal coating 14 is formed before the thin chromium film is removed.

In practice, the suspension board with circuit 1 described above can be produced using a production line including the roll-to-roll process. In the roll-to-roll process, for example a film of suspension board is formed by laminating the insulating base layer 3, the conductor layer 4, and the insulating cover layer 10 on the suspension board 2 continuously and then is cut off for each suspension board with circuit 1.

### EXAMPLE

While in the following, the present invention will be described in further detail with reference to Example and Comparative Example, the present invention is not limited thereto.

### Example 1

The following processes were carried out using the roll-to-roll process, to obtain a suspension board with circuit.

A suspension board of a stainless of 300 mm wide, 20 μm thick, and 120 m long was prepared (Cf. FIG. 2(a)). Then, after solution of polyamic acid resin was coated over the entire surface of the suspension board, the coated resin was heated at 100° C., to form a coating of the polyamic acid resin having a thickness of 25 μm (Cf. FIG. 2(b)). Then, the coating thus formed was exposed to light of 720 mJ/cm² through a photo mask and was heated at 180° C. Then, it was developed using alkaline developer (Cf. FIG. 2(c)). Thereafter, the coating was cured at a highest temperature of 420° C., whereby the insulating base layer of polyimide resin was formed with a predetermined pattern (Cf. FIG. 2(d)). The thickness of the insulating base layer thus formed was 10 μm.

Sequentially, a thin chromium film having a thickness of 400 Å and a thin copper film having a thickness of 700 Å were formed in sequence on the entire surface of the suspension board and insulating base layer by the sputtering process, to thereby form a seed film (Cf FIG. 2(e)).

The sputtering was performed using an electrode formed of zirconium on condition of the electric power of 1.0 kW and the processing time of 10 seconds. An amount of zirconium deposited on the surface of the suspension board immediately after completion of the sputtering was 1.0 atomic %.

Then, after a dry film photoresist was laminated on the seed film, it was exposed to light of 235 mJ/cm² through the photo mask and then was developed using alkaline developer. After these processes, a plating resist having a reverse pattern to the wiring circuit pattern was formed on the seed film (Cf. FIG. 3(f)).

Then, the conductor layer in the form of the wiring circuit pattern was formed by electrolysis copper plating on an area of the insulating base layer where the plating resist was not formed (Cf. FIG. 3(g)). The thickness of the conductor layer thus formed was 12 μm and the width of the lines of wire was 280 μm. The interval between the adjacent lines of wire was 480 cm.

Then, after the plating resist was stripped (FIG. 3(h)), the seed film on which the plating resist had been formed was removed by the chemical etching (Cf. FIG. 3(i)). Then, a metal coating of a hard, thin nickel film having a thickness of 0.1 μm was formed on a surface of the conductor layer and suspension board by electroless nickel plating (Cf. FIG. 3(j)).

The electroless nickel plating was performed using palladium hydrochloride solution, whose palladium concentration was 55 ppm and hydrochloric acid concentration was 115 g/L, as the electroless plating solution on condition that the solution temperature was 25° C. and the dipping time was 55 seconds. An amount of palladium deposited on the surface of the suspension board immediately after completion of the electroless plating was 9.9 atomic %.

Then, after solution of polyamic acid resin was coated over the entire surface of the insulating base layer and metal coating, the coated resin was heated at 100° C., to form a coating of the polyamic acid resin having a thickness of 20 μm (Cf. FIG. 4(k)). Then, the coating thus formed was exposed to light of 720 mJ/cm² through the photo mask and was heated at 180° C. Then, it was developed using alkaline developer and thereby was patterned so that the conductor layer was covered with the coating (FIG. 4(l)). Thereafter, the coating was cured at a highest temperature of 420° C., whereby the insulating cover layer of polyimide resin was formed with a predetermined pattern (Cf. FIG. 4(m)). The thickness of the insulating cover layer thus formed was 5 μm.

Then, the metal coating exposed from the surface of the suspension board and insulating cover layer was removed by the chemical etching (Cf. FIG. 4(n)). Then, after the dry film photoresist was laminated to cover the contour of the suspension board, except areas thereof where the gimbals and the location holes were to be formed, and was exposed to light of 105 mJ/cm², it was developed using alkaline developer, to form an etching resist. Thereafter, with the etching resist as a resist, the suspension board was etched by the chemical etching using ferric chloride solution and also punched out with the suspension board with circuit, to form the gimbals and the location holes (whose diameter was set at 0.5 mm) simultaneously in the suspension board with circuit (Cf. FIG. 4(o)).

An amount of zirconium deposited on the surface of the suspension board immediately before the chemical etching of the suspension board was 0.9 atomic %, and an amount of palladium deposited on the surface of the suspension board immediately before the chemical etching of the suspension board was 5.1 atomic %.

### Comparative Example 1

Except that the sputtering was performed using an electrode formed of zirconium on condition of the electric power of 0.1 kW and the processing time of 5 seconds and that the electroless nickel plating was performed using palladium hydrochloride solution, whose palladium concentration was 10 ppm and hydrochloric acid concentration was 150 g/L, as the electroless plating solution on condition that the solution temperature was 25° C. and the dipping time was 20 seconds, the same operation as in Example 1 was performed to obtain a suspension board with circuit.

An amount of zirconium deposited on the surface of the suspension board immediately after completion of the sputtering was 0.1 atomic %, and an amount of palladium deposited on the surface of the suspension board immediately after completion of the electroless plating was 0.2 atomic %.

Also, an amount of zirconium deposited on the surface of the suspension board immediately before the chemical etching of the suspension board was 0 atomic %, and an amount of palladium deposited on the surface of the suspension board immediately before the chemical etching of the suspension board was 0 atomic %.

Evaluation

The dimensional accuracy of the location holes in the suspension board with circuit formed in the final process of Example 1 and Comparative Example 1 was evaluated by measuring an average hole diameter, a maximum hole diameter, a minimum hole diameter, and standard deviation of each of the location holes of Example 1 and Comparative Example 1. The results are shown in TABLE 1.

TABLE 1

| | | Maximum | Minimum | |
|---|---|---|---|---|
| Example/Comparative | Average hole | hole | hole | Standard |
| Example | diameter | diameter | diameter | deviation |
| Example 1 | 0.5006 | 0.5044 | 0.4978 | 0.0015 |
| Comparative Example | 0.5032 | 0.5097 | 0.4941 | 0.0042 |
| 1 | | | | |

While the illustrative embodiments of the present invention are provided in the above description, such is for illustrative purpose only and it is not to be construed restrictively. Modification and variation of the present invention that will be obvious to those skilled in the art is to be covered by the following claims.

1. A production method of a suspension board with circuit comprising an etching process of etching a suspension board,
wherein the suspension board is etched in the etching process in the state that material harder to be etched than forming material of the suspension board is deposited on a surface of the suspension board.

2. The production method of the suspension board with circuit according to claim 1, wherein the forming material of the suspension board is stainless, and the material harder to be etched than the forming material of the suspension board is zirconium or palladium.

3. The production method of the suspension board with circuit according to claim 2, which further comprises a sputtering process of forming a thin conductive film on the surface of the suspension board by sputtering,
wherein zirconium is deposited on the surface of the suspension board by sputtering the thin conductive film in the sputtering process using an electrode formed of zirconium.

4. The production method of the suspension board with circuit according to claim 2, which further comprises an electroless plating process of forming a thin metal film on the surface of the suspension board by electroless plating,
wherein palladium is deposited on the surface of the suspension board by electroless-plating the thin metal film in the electroless plating process using a catalyst including palladium.
